(19) United States
(12) Patent Application Publication
(10) Pub. No.: US 2015/0333226 A1
(43) Pub. Date: Nov. 19, 2015

(54) STACKING STRUCTURE OF A LIGHT-EMITTING DEVICE

(71) Applicant: NATIONAL SUN YAT-SEN UNIVERSITY, Kaohsiung (TW)

(72) Inventors: I-Kai LO, Kaohsiung (TW); Cheng-Hung SHIH, Kaohsiung (TW); Bae-Heng TSENG, Kaohsiung (TW)

(21) Appl. No.: 14/661,663

(22) Filed: Mar. 18, 2015

(30) Foreign Application Priority Data
May 15, 2014 (TW) 103117190

(51) Int. Cl. H01L 33/26; H01L 33/42; H01L 33/28

(52) U.S. Cl. CPC H01L 33/26; H01L 33/28; H01L 33/42

(57) ABSTRACT

A stacking structure of a light-emitting device is disclosed. The stacking structure of the light-emitting device includes a substrate, a first semiconductor layer, a second semiconductor layer, a conducting layer, and two electrodes. The substrate is essentially made of a light-permeable, non-metallic material. The first semiconductor layer is arranged on the substrate and essentially made of a ternary compound with chalcopyrite phase. The second semiconductor layer is arranged on the first semiconductor layer. The conducting layer is arranged on the second semiconductor layer and essentially made of a light-permeable semiconducting material different from the material of the substrate. The two electrodes are respectively arranged on the substrate and the conducting layer. Thus, the problem of having difficulty in emitting the light outwards from the side of the light-emitting diode adjacent to the substrate, as commonly seen in the conventional light-emitting device, is overcome.

### BACKGROUND OF THE INVENTION

1. Field of the Invention

The present invention generally relates to a stacking structure of a light-emitting device and, more particularly, to a stacking structure of a light-emitting device capable of converting electrical energy into light energy.

2. Description of the Related Art

Light-emitting devices, such as light-emitting diodes or laser-emitting diodes, are capable of converting electrical energy into electroluminescent light energy for display, illumination and detection purposes. As an example of light-emitting diodes, the commercial light-emitting diodes are usually made of silicon. However, due to the indirect bandgap of silicon, the converting efficiency of the produced photoelectric device is insufficient and a thermal loss is resulted. This problem can be overcome by using another material with direct bandgap such as Copper Indium Selenide (CuInSe₂).

A conventional light-emitting diode is formed by growing a Copper Indium Selenide layer on a substrate made of Gallium Arsenide (GaAs), Silicon (Si), or Gallium Phosphide (GaP). Next, two electrodes are respectively arranged on the Copper Indium Selenide layer and the substrate, and direct-current electrical energy is provided to the light-emitting diode for generating light energy.

However, the bandgaps of Gallium arsenide, silicon, and Gallium Phosphide used in the conventional light-emitting diode are respectively 1.42, 1.04, and 2.27 eV. The bandgaps of Gallium Arsenide, Silicon, and Gallium Phosphide are narrow; therefore they absorb the visible light energy generated from the light-emitting diode. Furthermore, the substrate made of Gallium arsenide, silicon, or Gallium Phosphide is impermeable to visible light, thus preventing the visible light from emitting outwards from the side of the light-emitting diode adjacent to the substrate, leading to a lower light generating efficiency. Moreover, Gallium arsenide is toxic, and causes environmental pollution during the production of the light-emitting diode. The pollution may be reduced with a specific treatment, but may increase the production cost.

In light of above, it is necessary to improve the conventional light-emitting device.

### SUMMARY OF THE INVENTION

It is therefore the objective of this invention to provide a stacking structure of a light-emitting device capable of emitting the light outwards from the side of the stacking structure of the light-emitting device adjacent to the substrate.

It is another object of this invention to provide a stacking structure of a light-emitting device capable of preventing the light from being absorbed by the substrate.

It is still another object of the this invention to provide a stacking structure of a light-emitting device without using GaAs as the material of the substrate.

In an embodiment, a stacking structure of a light-emitting device includes a substrate, a first semiconductor layer, a second semiconductor layer, a conducting layer and two electrodes. The conducting base is essentially made of a light-permeable, non-metallic material. The first semiconductor layer is arranged on the substrate and essentially made of a ternary compound with chalcopyrite phase. The second semiconductor layer is arranged on the first semiconductor layer. The conducting layer is arranged on the second semiconductor layer and essentially made of a light-permeable semiconducting material different from the light-permeable, non-metallic material of the substrate. The two electrodes are respectively arranged on the substrate and the conducting layer.

In a form shown, the substrate is essentially made of a light-permeable III-Nitride.

In the form shown, the light-permeable III-Nitride is Gallium Nitride or Aluminum Nitride.

In the form shown, the Gallium Nitride is grown along the c-axis.

In the form shown, the III-Nitride includes a group 1 element, a group 3 element, and a group 6 element with a mole ratio of 1:1:2, wherein the group 1 element is Copper, the group 3 element is Indium, Gallium or Aluminum, and the group 6 element is Selenium or Sulphur.

In the form shown, the second semiconductor layer is essentially made of Cadmium Sulphide, Zinc Sulphide, Zinc Hydroxide or Indium Sulphide.

In the form shown, the conducting layer is essentially made of Zinc Oxide or Indium Tin Oxide.

In the form shown, the stacking structure of the light-emitting device further includes a buffer layer arranged between the first and second semiconductor layers.

In the form shown, the buffer layer is essentially made of Indium Nitride.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a cross sectional view of a stacking structure of a light-emitting device according to a first embodiment of this invention.

FIG. 2 is a cross sectional view of a stacking structure of a light-emitting device according to a second embodiment of this invention.

FIG. 3a is a bright field image of the stacking structure of the light-emitting device with the first semiconductor layer being CuInSe₂ (112).

FIG. 3b is a SAD image of the stacking structure of the light-emitting device with the first semiconductor layer being CuInSe₂.

FIG. 3c is a SAD image of the stacking structure of the light-emitting device with the first semiconductor layer being CuInSe₂ and the substrate being GaN.

FIG. 3d is a SAD image of the stacking structure of the light-emitting device with the substrate being GaN.

In the various figures of the drawings, the same numerals designate the same or similar parts. Furthermore, when the terms “first”, “second”, “third”, “fourth”, “inner”, “outer”, “top”, “bottom”, “front”, “rear” and similar terms are used hereinafter, it should be understood that these terms have reference only to the structure shown in the drawings as it would appear to a person viewing the drawings, and are utilized only to facilitate describing the invention.

### DETAILED DESCRIPTION OF THE INVENTION

The term “electroluminescence effect” mentioned hereinafter in this application refers to a light-emitting effect resulting from the combination of the electrons and holes that takes place in a P-N junction of a diode when an electric current flows through the P-N junction, as it would be understood by a person having ordinary skill in the art.

The term “indirect bandgap” mentioned hereinafter in this application refers to the fact that the jumping of the electrons between the valence band and the conduction band is related to a change in the momentum of crystal lattices, which not only generates heat but also reduces the photoelectric conversion efficiency, as it would be understood by a person having ordinary skill in the art.

The term “direct bandgap” mentioned hereinafter in this application refers to the fact that the jumping of the electrons between the valence band and the conduction band is not related to a change in the momentum of crystal lattices, which not only generates heat but also reduces the photoelectric conversion efficiency, as it would be understood by a person having ordinary skill in the art.

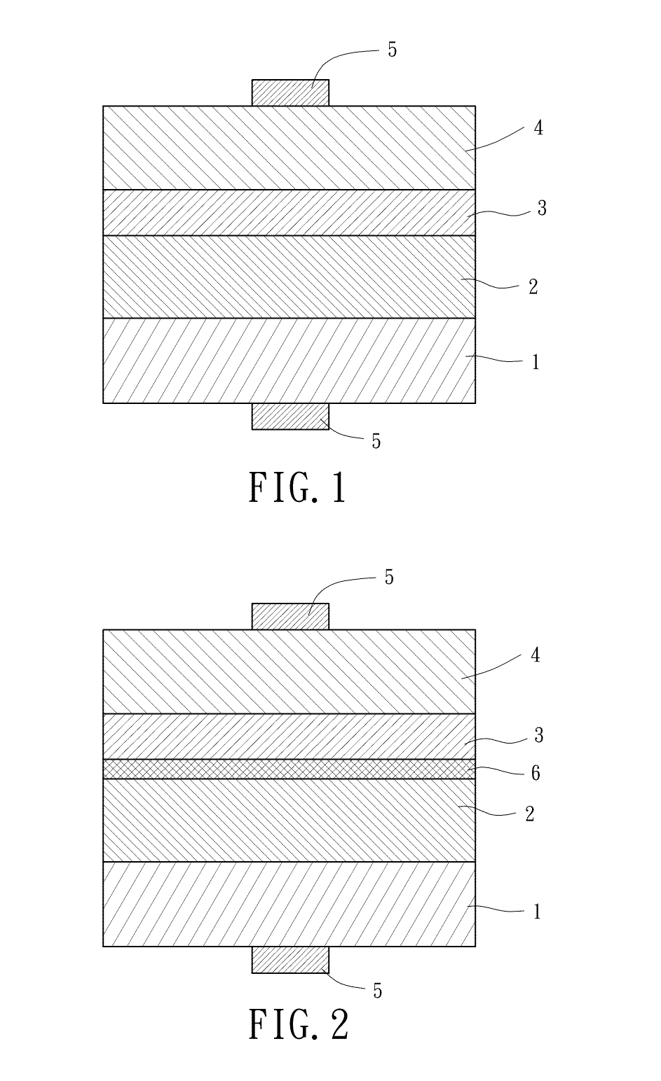

Please refer to FIG. 1, which shows a cross sectional view of a stacking structure of a light-emitting device according to a first embodiment of the present invention. The stacking structure of the light-emitting device includes a substrate 1, a first semiconductor layer 2, a second semiconductor layer 3, a conducting layer 4 and two electrodes 5. The first semiconductor layer 2, the second semiconductor layer 3 and the conducting layer 4 are sequentially stacked on the substrate 1, and the two electrodes are respectively arranged on the substrate 1 and the conducting layer 4.

Please refer to FIG. 1 again, the substrate 1 may be made of a light-permeable material, which is preferably a light-permeable, non-metallic material, such as light-permeable III-Nitride (group 3 Nitride). The III-Nitride may preferably be Gallium Nitride (GaN) or Aluminum Nitride (AlN) transparent to visible light, but is not limited thereto. The III-Nitride can conduct electrical energy for the stacking structure of the light-emitting device, and transmit light energy produced by the stacking structure of the light-emitting device. In addition, the III-Nitride provides a higher electron mobility, and its direct bandgap may increase the efficiency of photoelectric conversion. Unlike the arsenide used in the conventional light-emitting device, III-Nitride is non-toxic. In this embodiment, the substrate 1 is, but not limited to, GaN and may be epitaxially formed. Since the single-crystal GaN (which is preferably GaN grown along the c-axis) is light-permeable, the substrate 1 allows transmitting the light generated from the stacking structure of the light-emitting device. Furthermore, the direct bandgap of GaN can convert electrical energy into light energy directly when the electrons and holes combine with each other, thus increasing the light generating efficiency. There is almost no loss in kinetic energy during the energy conversion process, preventing the generation of heat. Due to the wide bandgap (3.42 eV) of GaN, a deep quantum well is formed between the substrate 1 and the first semiconductor layer 2. Thus, the amount of the carrier flowing into the first semiconductor layer 2 is limited, and the light generating efficiency of the light-emitting device is improved.

Please refer to FIG. 1 again, the first semiconductor layer 2 is arranged between the substrate 1 and the second semiconductor layer 3. The first semiconductor layer 2 forms a P-N junction, and is preferably made of a ternary compound with chalcopyrite phase. The ternary compound includes a group 1 element, a group 3 element, and a group 6 element at a mole ratio of 1:1:2 (I-III-VI₂). The group 1 element may be Copper (Cu), the group 3 element may be Indium (In), Gallium (Ga) or Aluminum (Al), and the group 6 element may be Selenium (Se) or Sulphur (S). However, this is not taken as a limited sense. The ternary compound with chalcopyrite phase may increase the arrangement regularity of the interface between the first semiconductor layer 2 and the substrate 1. In this embodiment, the first semiconductor layer 2 may be III-Nitride epitaxially grown on the ternary compound by MBE (molecular beam epitaxy), such as Copper Indium Selenide (CuInSe₂, CISe), Copper Gallium Selenide (CuGaSe₂, CGSe), Copper Aluminum Selenide (CuAlSe₂, CASe), Copper Indium Sulphide (CuInS₂, CIS), Copper Gallium Sulphide (CuGaS₂, CGS), or Copper Aluminum Sulphide (CuAlS₂, CAS). In addition, the first semiconductor layer 3 may also be a quaternary compound with chalcopyrite phase, such as Cu(In,Ga)Se₂, Cu(Al,In)Se₂ or Cu(Al,Ga)Se₂. As an example of CuInSe₂ epitaxially grown on single-crystal GaN, the interface between GaN and CuInSe₂ has no impurity produced by the chemical reaction. Thus, the light generating efficiency of the photoelectric device is increased, and the electrical reliability of the photoelectric device is further ensured. Since the bandgap off set between CuInSe₂ (1.04 eV) and GaN (3.42 eV) is 2.38 eV, a deep potential energy well is formed, thus increasing the light generating efficiency of the photoelectric device.

Please refer to FIG. 1 again, the second semiconductor layer 3 is arranged between the first semiconductor layer 2 and the conducting layer 4. The second semiconductor layer 3 may be made of a N-type semiconducting material, such as Cadmium Sulphide (CdS), Zinc Sulphide (ZnS), Zinc Hydroxide (Zn(OH)₂), or Indium Sulphide (InS). The first semiconductor layer 2 and the second semiconductor layer 3 can convert electrical energy into electroluminescent light energy, and the working principle thereof is known to the person having ordinary skill in the art. In this embodiment, the second semiconductor 3 is Cadmium Sulphide formed by chemical bathing and sputtering on the first semiconductor layer 2.

Please refer to FIG. 1 again, the conducting layer 4 arranged on the second semiconductor layer 3 is essentially made of a light-permeable semiconducting material preferably, such as semiconducting material of Zinc Oxide or Indium Tin Oxide. The conducting layer 4 conducts electrical energy for the stacking structure of the light-emitting structure, and transmits light energy generated by the stacking structure of the light-emitting device. However, the material of the conducting layer 4 is different from that of the substrate 1. In this embodiment, the conducting layer 4 is Zinc Oxide formed by chemical bathing and sputtering on the second semiconductor layer 3, but is not limited thereto. Due to the direct bandgap of Zinc Oxide, the light generating efficiency is increased, and the amount of heat generated during the photoelectric conversion process is reduced.

Please refer to FIG. 1 again, the two electrodes are preferably made of a material with excellent conductivity such as Gold (Au), Platinum (Pt), or Aluminum (Al). The two electrodes are respectively arranged on the substrate 1 and the conducting layer 4 for conducting electrical energy. In this embodiment, the two electrodes are made of Aluminum, but are not limited thereto.

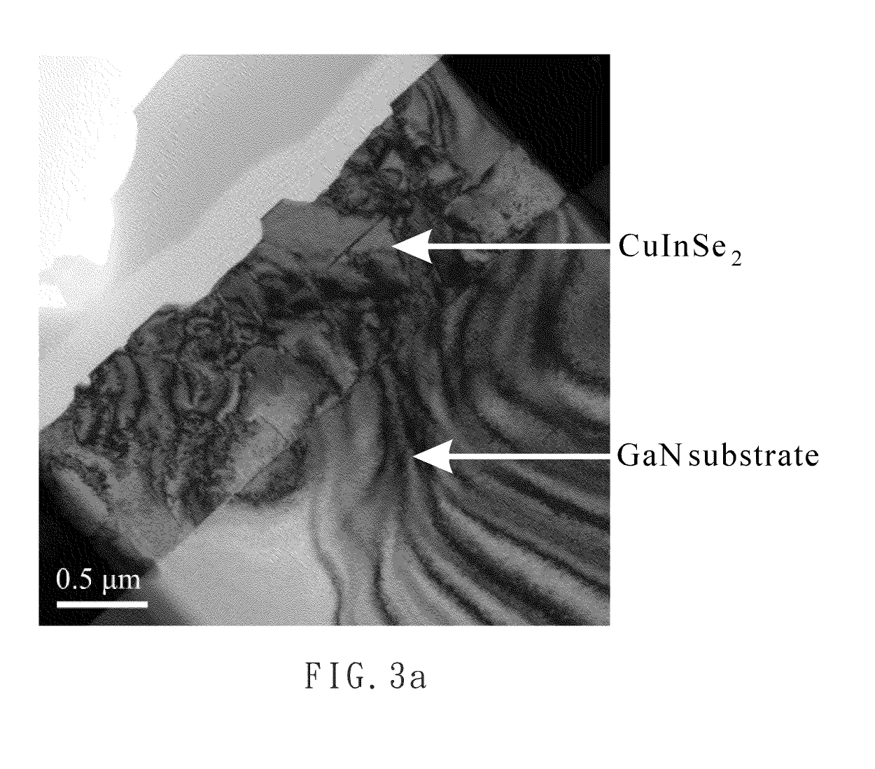

Please refer to FIG. 2, which shows a cross sectional view of a stacking structure of a light-emitting device according to a second embodiment of the present invention. In the second embodiment, the stacking structure of the light-emitting device includes the substrate 1, the first semiconductor layer 2, the second semiconductor layer 3, the conducting layer 4 and the electrodes 3 similar to the first embodiment, and further includes a buffer layer 6 arranged between the first semiconductor layer 2 and the second semiconductor layer 3. The buffer layer 6 is essentially made of Indium Nitride (InN) and serves as a far-infrared light-emitting layer. The bandgaps of InN and CISe are 0.7 and 1.04 eV respectively; therefore InN and CISe may generate the far-infrared light. Thus, the light-emitting frequency range is expanded and the amount of the generated light energy is increased. In this embodiment, the buffer layer 6 may be formed epitaxially, but is not limited thereto.

Please refer to FIGS. 1 and 2, when the stacking structure of the light-emitting device is in use, direct-current (DC) electrical energy may be supplied to the first semiconductor layer 2 and the semiconductor layer 3 through the two electrodes 5, the substrate 1, the conducting layer 4 and the buffer layer 6. Therefore, the first semiconductor layer 2 and the second semiconductor layer 3 may convert the electrical energy into light electroluminescent energy, serving as a photoelectric device such as a light-emitting diode, but is not limited thereto. The working principle thereof is known to the person ordinarily skilled in the art, so it is not described herein for brevity.

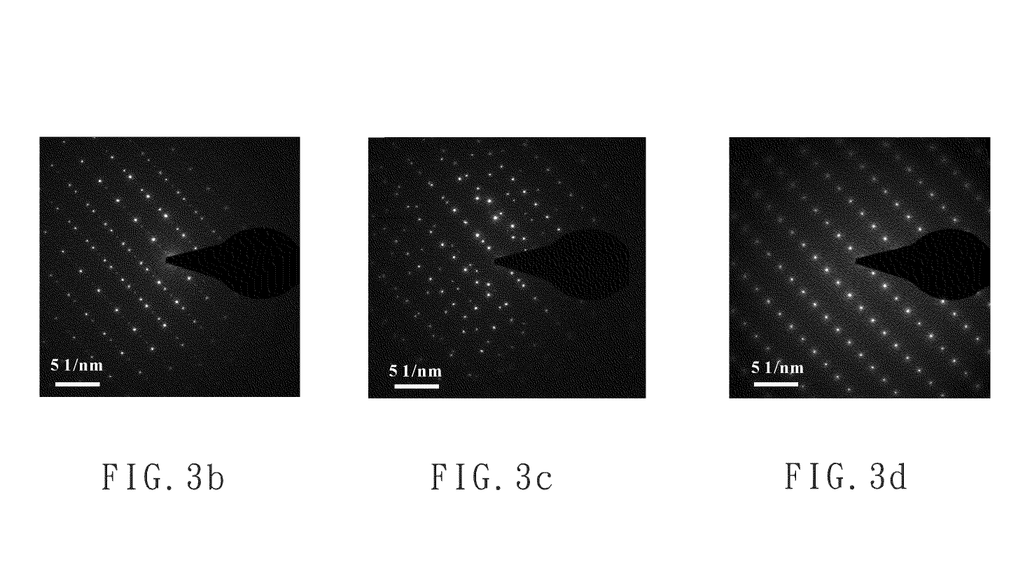

FIG. 3a is a bright field image of the stacking structure of the light-emitting device with the first semiconductor layer being CuInSe₂(112). FIG. 3b is an SAD (selected area diffraction) image of the stacking structure of the light-emitting device with the first semiconductor layer being CuInSe₂. FIG. 3c is an SAD image of the stacking structure of the light-emitting device with the first semiconductor layer being CuInSe₂ and the substrate being GaN. FIG. 3d is an SAD image of the stacking structure of the light-emitting device with the substrate being GaN. According to FIGS. 3b and 3c, the diffraction image of the interface between CuInSe₂ and GaN are arranged in high regularity, thus proving that CuInSe₂ can actually be epitaxially grown on GaN, and the interface between CuInSe₂ and GaN is capable of increasing the photoelectric conversion efficiency. As a result, the stacking structure of the light-emitting device in the present invention provides a higher photoelectric conversion efficiency in comparison with the conventional light-emitting device.

It is noted that since the lattice fault (defect) between the crystal materials causes the reduction in light generating efficiency, it becomes the main factor that affects the performance of the light-emitting semiconductor device. The lattice fault is caused by lattice mismatch and crystal system mismatch. One of the examples of the lattice mismatch is that when GaN is grown on a sapphire substrate, there exists a lattice mismatch between the lattices of the sapphire substrate and GaN. Although both the sapphire substrate and GaN are hexagonal, the lattice mismatch still exists due to different lattice sizes therebetween. On the other hand, one of the examples of the crystal system mismatch is that when GaN is grown on the silicon substrate, there exists a mismatch between the crystal systems of the silicon substrate and GaN since the silicon substrate is of cubic crystal system and GaN is of hexagonal crystal system. This is explained in the paper entitled “Structural and electrical characterization of GaN thin film on Si (100)”, as published by Gajanan Niranjan Chaudhari, Vijay Ramkrishna Chinchamalatpure and Sharada Arvind Ghosh in American Journal of Analytical Chemistry, 2011, 2, 984-988. Furthermore, the crystal system mismatch often comes with the lattice mismatch. It can be known from semiconductor physics theory that the epitaxial operation will not be able to be smoothly performed due to the lattice fault caused by a large lattice mismatch rate. For example, the lattice mismatch rate between GaN and CuInSe₂ is larger than 28.5%, leading to a high potential of failure of the epitaxial operation. However, it has been proven through experiments that the application is able to reduce the lattice mismatch rate from 28.5% (theoretical value) to 2.8% (actual value) when CuInSe₂(112) is combined with GaN(0001). In light of this, it becomes possible to grow CuInSe₂(112) on GaN(0001), which overthrows the traditional perception that the epitaxial operation cannot be performed under a large lattice mismatch rate. In this regard, the GaN(0001) material appears to be transparent to visible light, which does solve the problem of having difficulty in emitting light from the side of the light-emitting device adjacent to the substrate.

Based on the above disclosure, the stacking structure of the light-emitting device is characterized as follows. The stacking structure of the light-emitting device includes the substrate, the first semiconductor layer, the second semiconductor layer, the conducting layer and the two electrodes. The substrate is essentially made of a light-permeable, non-metallic material. The first semiconductor layer is arranged on the substrate, and is essentially made of a ternary compound with chalcopyrite phase. The second semiconductor layer is arranged on the first semiconductor layer. The conducting layer is arranged on the second semiconductor layer, and is essentially made of a light-permeable semiconducting material different from the material of the substrate. The two electrodes are respectively arranged on the substrate and the conducting layer. Furthermore, the stacking structure of the light-emitting device includes the buffer layer arranged between the first and second semiconductor layers. Thus, the stacking structure of the light-emitting device can emit light from the side of the stacking structure of the light-emitting device adjacent to the substrate, as well as from the other side of the light-emitting device opposite to the substrate. Moreover, the stacking structure of the light-emitting device may prevent light energy absorbing by the substrate, thus improving the light generating efficiency and ensuring reliability.

Although the invention has been described in detail with reference to its presently preferable embodiments, it will be understood by one of ordinary skill in the art that various modifications can be made without departing from the spirit and the scope of the invention, as set forth in the appended claims.

1. A stacking structure of a light-emitting device, comprising:
a substrate essentially made of a light-permeable, non-metallic material;
a first semiconductor layer arranged on the substrate and essentially made of a ternary compound with chalcopyrite phase;
a second semiconductor layer arranged on the first semiconductor layer;
a conducting layer arranged on the second semiconductor layer and essentially made of a light-permeable semiconducting material different from the light-permeable, non-metallic material of the substrate; and
two electrodes respectively arranged on the substrate and the conducting layer.

2. The stacking structure of the light-emitting device as claimed in claim 1, wherein the substrate is essentially made of a light-permeable III-Nitride.

3. The stacking structure of the light-emitting device as claimed in claim 2, wherein the light-permeable III-Nitride is Gallium Nitride or Aluminum Nitride.

4. The stacking structure of the light-emitting device as claimed in claim 3, wherein the Gallium Nitride is grown along the c-axis.

5. The stacking structure of the light-emitting device as claimed in claim 1, wherein the III-Nitride comprises a group 1 element, a group 3 element, and a group 6 element with a mole ratio of 1:1:2, wherein the group 1 element is Copper, the group 3 element is Indium, Gallium or Aluminum, and the group 6 element is Selenium or Sulphur.

6. The stacking structure of the light-emitting device as claimed in claim 1, wherein the second semiconductor layer is essentially made of Cadmium Sulphide, Zinc Sulphide, Zinc Hydroxide or Indium Sulphide.

7. The stacking structure of the light-emitting device as claimed in claim 1, wherein the conducting layer is essentially made of Zinc Oxide or Indium Tin Oxide.

8. The stacking structure of the light-emitting device as claimed in claim 1, further comprising a buffer layer arranged between the first and second semiconductor layers.

9. The stacking structure of the light-emitting device as claimed in claim 8, wherein the buffer layer is essentially made of Indium Nitride.
